(19) United States
(12) Patent Application Publication
(10) Pub. No.: US 2024/0397789 A1
(43) Pub. Date: Nov. 28, 2024

(54) DISPLAY DEVICE

(71) Applicant: Samsung Display Co., Ltd., Yongin-si (KR)

(72) Inventors: KEUNWOO PARK, Yongin-si (KR); TAEHOON KIM, Yongin-si (KR); JAE CHEOL PARK, Yongin-si (KR); DANBI YANG, Yongin-si (KR); KANGSEOB JEONG, Yongin-si (KR)

(21) Appl. No.: 18/609,815

(22) Filed: Mar. 19, 2024

(30) Foreign Application Priority Data
May 23, 2023 (KR) 10-2023-0066564

(51) Int. Cl. H10K 59/80; H10K 59/122; H10K 59/38; H10K 102/00

(52) U.S. Cl. CPC H10K 59/8722; H10K 59/122; H10K 59/38; H10K 2102/331

(57) ABSTRACT

A display device includes a first display substrate including a first base layer including a display area and a non-display area adjacent to the display area, a second display substrate spaced apart from the first display substrate and including a second base layer including pixel areas respectively overlapping the display area and a peripheral area adjacent to the pixel areas and color filters on the second base layer, and a sealing member between the first display substrate and the second display substrate and overlapping the non-display area.

### CROSS-REFERENCED TO RELATED APPLICATION

The present application claims priority to and the benefit of Korean Patent Application No. 10-2023-0066564, filed on May 23, 2023, in the Korean Intellectual Property Office, the entire content of which is incorporated herein by reference.

### BACKGROUND

### 1. Field of Disclosure

Aspects of some embodiments of the present disclosure relate to a display device.

### 2. Description of the Related Art

As a display panel, an emissive type display panel that generates a light by itself and emits the light and a transmissive type display panel that transmits a source light generated by a light source after changing optical properties of the source light may be used. Quantum dots may be used to change the optical properties of the source light in the transmissive type display panel.

The above information disclosed in this Background section is only for enhancement of understanding of the background and therefore the information discussed in this Background section does not necessarily constitute prior art.

### SUMMARY

Aspects of some embodiments of the present disclosure relate to a display device. For example, aspects of some embodiments of the present disclosure relate to a display device including two display substrates coupled with each other and quantum dots.

Aspects of some embodiments of the present disclosure include a display device with relatively improved reliability by preventing or reducing moisture and oxygen permeated through a capping layer from reaching an inorganic layer in a display panel including two display substrates bonded with each other through a vacuum-pressure process.

Aspects of some embodiments of the present disclosure include a display device including a first display substrate including a first base layer including a display area and a non-display area adjacent to the display area, a second display substrate spaced apart from the first display substrate and including a second base layer including pixel areas overlapping the display area and a peripheral area adjacent to the pixel areas and color filters on the second base layer and a sealing member between the first display substrate and the second display substrate and overlapping the non-display area.

According to some embodiments, the first display substrate includes light emitting elements respectively overlapping the pixel areas, an encapsulation layer including a first inorganic layer covering the light emitting elements, a second inorganic layer, and a first organic layer between the first inorganic layer and the second inorganic layer, banks provided with openings defined therethrough to respectively overlap the pixel areas and arranged spaced apart from each other on the encapsulation layer, light control patterns respectively in the openings, a capping layer covering the banks and the light control patterns, and a second organic layer between the second inorganic layer and the capping layer in the non-display area.

According to some embodiments, one light control pattern among the light control patterns includes the same material as the second organic layer.

According to some embodiments, the material includes titanium oxide (TiO₂).

According to some embodiments, the other light control patterns except the one light control pattern among the light control patterns include a quantum dot.

According to some embodiments, at least a portion of the first inorganic layer is in contact with the second inorganic layer in the non-display area, and an end of the first inorganic layer and an end of the second inorganic layer, which are in the non-display area and face the sealing member, are covered by the second organic layer.

According to some embodiments, an end of the capping layer, which is in the non-display area and faces the sealing member, is spaced apart from the end of the first inorganic layer and the end of the second inorganic layer with the second organic layer interposed therebetween.

According to some embodiments, the second organic layer is spaced apart from the banks.

According to some embodiments, a portion of an upper surface of the second organic layer and a side surface of the second organic layer adjacent to the sealing member are exposed without being covered by the capping layer.

According to some embodiments, the upper surface of the second organic layer and a side surface of the second organic layer adjacent to the sealing member are covered by the capping layer.

According to some embodiments, the upper surface of the second organic layer is flat.

According to some embodiments, the second organic layer includes a first part and a second part, the first part is covered by the second inorganic layer and the capping layer, at least a portion of the second part is covered by the second inorganic layer and the capping layer, and the first part is spaced apart from the second part.

According to some embodiments, the first display substrate includes insulating layers on the first display substrate and dam patterns in the non-display area and including a same material as at least one of the insulating layers.

According to some embodiments, a boundary of the first organic layer is defined by one of the dam patterns, and at least a portion of the dam patterns is covered by the first inorganic layer.

According to some embodiments, the second display substrate includes a low refractive index layer on a lower surface of the color filters to cover the color filters and an upper cover layer on a lower surface of the low refractive index layer to cover the low refractive index layer.

According to some embodiments, a separation space between the first display substrate and the second display substrate is filled with a filling member, and the filling member includes an organic material.

According to some embodiments, the filling member covers the capping layer.

Aspects of some embodiments of the present disclosure include a display device including a first display substrate including a first base layer including a display area and a non-display area adjacent to the display area, a second display substrate spaced apart from the first display substrate and including a second base layer including pixel areas overlapping the display area and a peripheral area adjacent to the pixel areas and color filters on the second base layer, and a sealing member between the first display substrate and the second display substrate and overlapping the non-display area.

According to some embodiments, the first display substrate includes light emitting elements respectively overlapping the pixel areas, an encapsulation layer including a first inorganic layer covering the light emitting elements, a second inorganic layer, and a first organic layer between the first inorganic layer and the second inorganic layer, banks provided with openings defined therethrough to respectively overlap the pixel areas and arranged spaced apart from each other on the encapsulation layer, light control patterns respectively in the openings, and a second organic layer on the second inorganic layer in the non-display area. According to some embodiments, the second organic layer includes a same material as one of the light control patterns.

According to some embodiments, the first display substrate includes a capping layer that covers at least a portion of each of the banks, the light control patterns, the second inorganic layer, the first base layer, and the second organic layer, and an end of the capping layer and an end of the second inorganic layer are spaced apart from each other with the second organic layer interposed therebetween in the non-display area.

According to some embodiments, the material includes titanium oxide (TiO₂).

According to some embodiments, the other light control patterns except the one light control pattern among the light control patterns include a quantum dot.

According to some embodiments of the present disclosure, as the organic layer is formed between the inorganic layer and the capping layer, moisture, contaminants, and/or oxygen permeated through the capping layer may be prevented from reaching the inorganic layer. Thus, the reliability of the display device may be relatively improved.

### BRIEF DESCRIPTION OF THE DRAWINGS

The above and other characteristics of embodiments according to the present disclosure will become more readily apparent by reference to the following detailed description when considered in conjunction with the accompanying drawings wherein:

FIG. 1A is a perspective view of a display device according to some embodiments of the present disclosure;

FIG. 1B is a plan view of a display device according to some embodiments of the present disclosure;

FIG. 1C is a cross-sectional view of a display device taken along a line I-I′ of FIG. 1B;

FIG. 2 is a plan view of a display substrate according to some embodiments of the present disclosure;

FIG. 3 is an enlarged plan view of a display area according to some embodiments of the present disclosure;

FIG. 4 is a cross-sectional view of a display device taken along a line II-II′ of FIG. 3;

FIG. 5 is a cross-sectional view of a display device taken along a line III-III′ of FIG. 1B;

FIGS. 6A to 6H are cross-sectional views illustrating a method of manufacturing a display device according to some embodiments of the present disclosure;

FIG. 7 is a cross-sectional view of a display device according to some embodiments of the present disclosure; and

FIG. 8 is a cross-sectional view of a display device according to some embodiments of the present disclosure.

### DETAILED DESCRIPTION

The present disclosure may be variously modified and realized in many different forms, and thus aspects of some embodiments will be illustrated in the drawings and described in more detail hereinbelow. However, embodiments according to the present disclosure should not be limited to the specific disclosed forms, and be construed to include all modifications, equivalents, or replacements included in the spirit and scope of the present disclosure.

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display device according to some embodiments of the present disclosure will be described in more detail with reference to accompanying drawings.

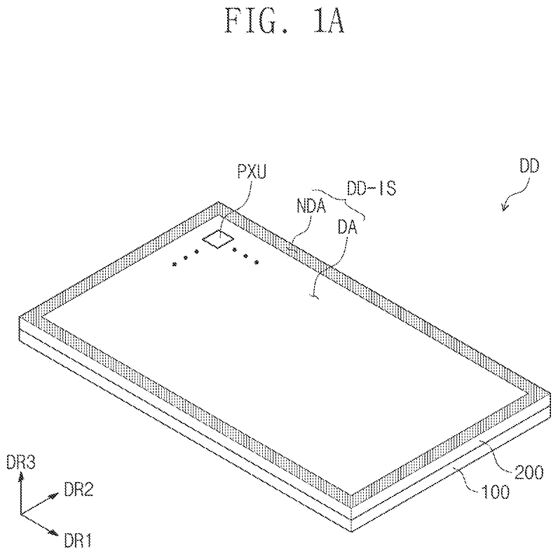

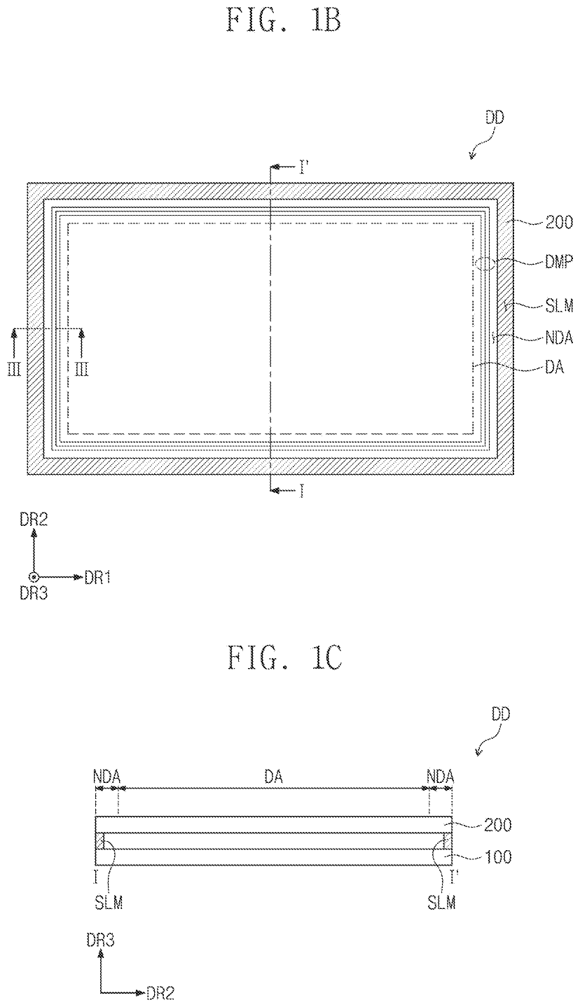

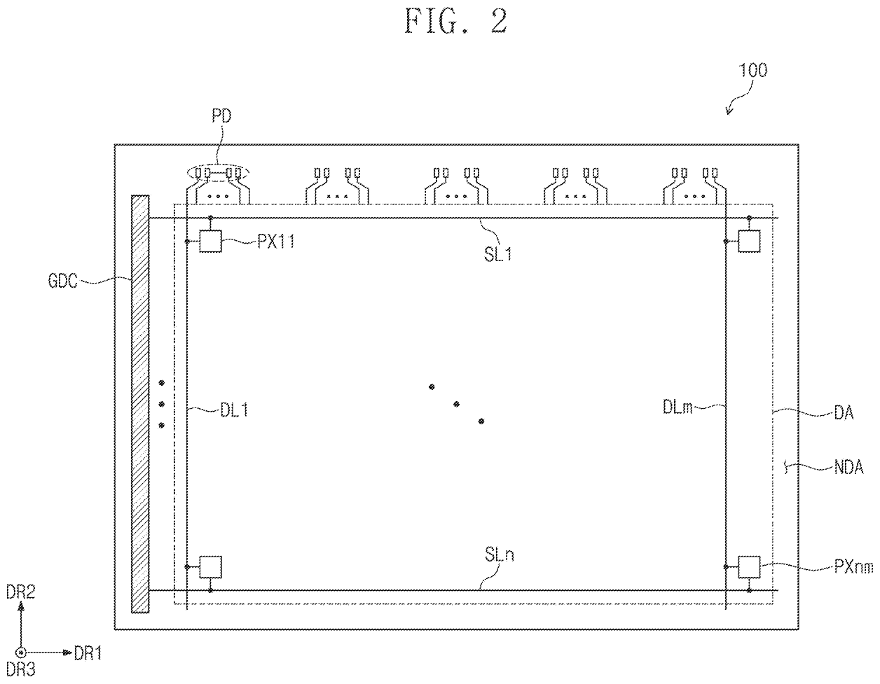

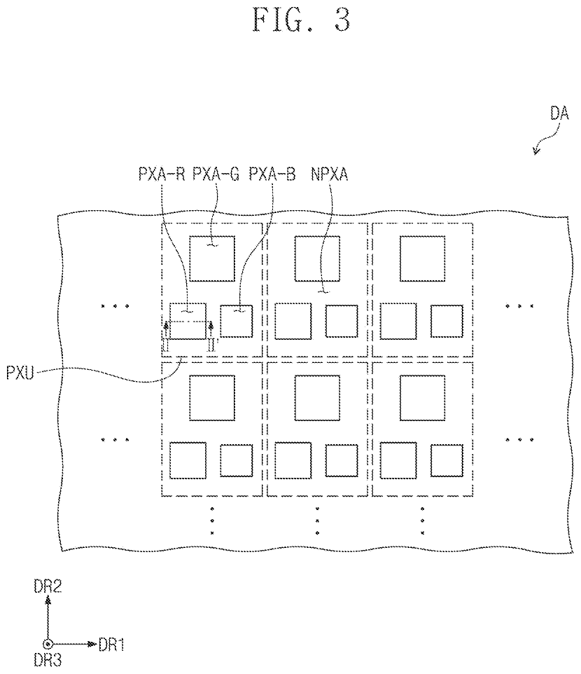

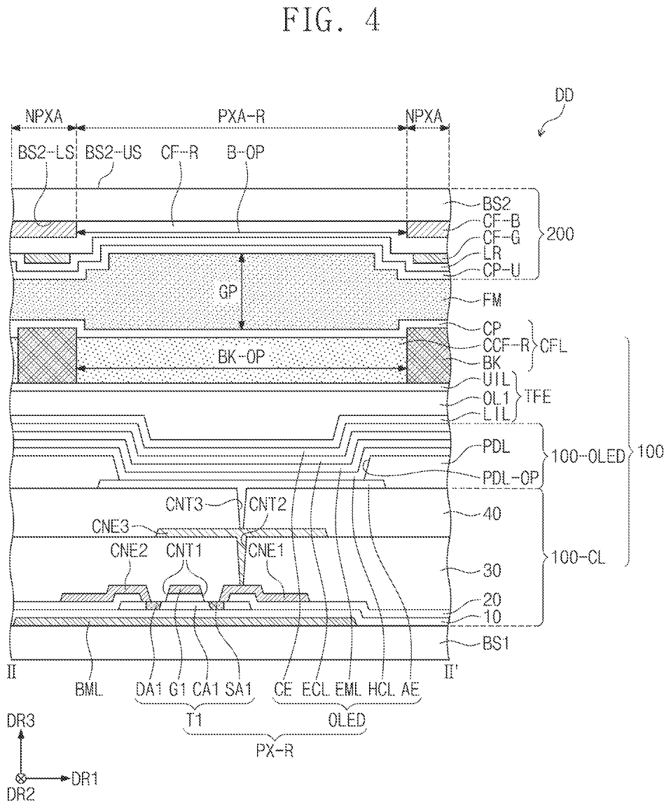

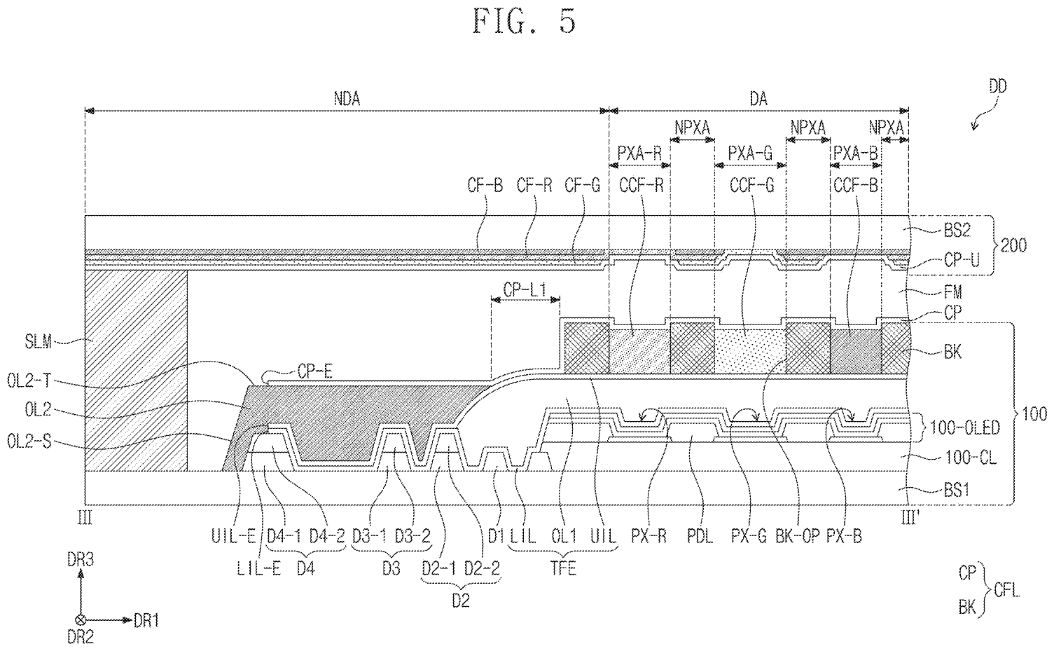

FIG. 1A is a perspective view of a display device DD according to some embodiments of the present disclosure. FIG. 1B is a plan view of the display device DD according to some embodiments of the present disclosure. FIG. 1C is a cross-sectional view of the display device DD taken along a line I-I′ of FIG. 1B. FIG. 2 is a plan view of a display substrate 100 according to some embodiments of the present disclosure. FIG. 3 is an enlarged plan view of a display area DA according to some embodiments of the present disclosure. FIG. 4 is a cross-sectional view of the display device DD taken along a line II-II′ of FIG. 3. FIG. 5 is a cross-sectional view of the display device DD taken along a line III-III′ of FIG. 1B.

Referring to FIG. 1A, the display device DD may include a display surface DD-IS to display an image IM through to a front surface thereof. The display device DD may display the image IM through the display surface DD-IS toward a third direction DR3, which is substantially parallel to a plane defined by a first direction DR1 and a second direction DR2. The third direction DR3 may intersect each of the first direction DR1 and the second direction DR2, and a normal line direction of the display surface DD-IS may be substantially parallel to the third direction DR3. The image IM displayed through the display surface DD-IS may include still images (e.g., static images) as well as a video images (e.g., moving images).

In the present embodiments, front (or upper) and rear (or lower) surfaces of each component of the display device DD may be defined with respect to a direction in which the image IM is displayed. The front and rear surfaces may be opposite to each other in the third direction DR3. Meanwhile, directions indicated by the first, second, and third directions DR1, DR2, and DR3 are relative to each other, and thus, the directions indicated by the first, second, and third directions DR1, DR2, and DR3 may be changed to other directions.

The display device DD may include a display area DA and a non-display area NDA. Unit pixels PXU may be arranged in the display area DA, and the unit pixels PXU may emit a light in response to electrical signals to display the image IM through the display area DA. The unit pixels PXU may not be arranged in the non-display area NDA. The non-display area NDA may be defined along an edge of the display surface DD-IS and may surround the display area DA.

The display device DD may be activated in response to electrical signals. The display device DD may include various embodiments to provide the image IM to a user. As an example, the display device DD may be applied to a large-sized electronic item, such as a television set, an outdoor billboard, etc., and a small and medium-sized electronic item, such as a mobile phone, a tablet computer, a navigation unit, a game unit, etc. However, these are merely examples, and the display device DD may be applied to other electronic devices as long as they do not depart from the concept of the present disclosure.

The display device DD may be flexible. The term “flexible” used herein refers to the property of being able to be bent from a structure that is completely bent to a structure that is bent at the scale of a few nanometers. For example, the display device DD may be a curved display device or a foldable display device. According to some embodiments, the display device DD may be rigid.

Referring to FIG. 1A, the unit pixels PXU may be arranged in rows and columns in the display device DD. The unit pixel PXU may be the smallest repeating unit, and one unit pixel PXU may include at least one pixel area PXA-R, PXAG, and PXA-B (refer to FIG. 3). The one unit pixel PXU may include a plurality of pixel areas PXA-R, PXAG, or PXA-B (refer to FIG. 3) that provide lights having different colors from each other.

Referring to FIGS. 1B and 1C, the display device DD may include a first display substrate 100 and a second display substrate 200. The second display substrate 200 may be arranged to be spaced apart upward from the first display substrate 100.

A cell gap GP (refer to FIG. 4) may be a space defined between the first display substrate 100 and the second display substrate 200. The cell gap GP may be maintained by a sealing member SLM.

The sealing member SLM may be located between the first display substrate 100 and the second display substrate 200 and may overlap the non-display area NDA. Referring to FIG. 1B, the sealing member SLM may be aligned with an edge of the second display substrate 200 when viewed in a plane (or in a plan view, or a direction perpendicular to a display surface or from the direction DR3), however, embodiments according to the present disclosure are not limited thereto or thereby. The sealing member SLM may hold the second display substrate 200 and the first display substrate 100 so that the second display substrate 200 and the first display substrate 100 are spaced apart from each other by a distance (e.g., a set or predetermined distance) and may prevent or reduce instances of external oxygen, contaminants, and/or moisture entering the second display substrate 200 and the first display substrate 100.

The sealing member SLM may include a binder resin and inorganic fillers mixed with the binder resin. The sealing member SLM may further include other additives. The additives may include an amine-based curing agent and a photoinitiator. The additives may further include a silane-based additive and an acrylic-based additive. The sealing member SLM may include an inorganic-based material such as a frit.

FIGS. 1B and 1C show the structure in which areas of surfaces of the first display substrate 100 and the second display substrate 200, which face the third direction DR3, are the same as each other, however, embodiments according to the present disclosure are not limited thereto or thereby.

In FIG. 1B, a dam pattern DMP is schematically shown as a solid line. The dam pattern DMP may overlap the non-display area NDA and may be located on the first display substrate 100. FIG. 1B shows three dam patterns, however, this is merely an example, and the number of the dam patterns may be adjusted as needed. At least one dam pattern among the dam patterns may have a closed-line shape. In FIG. 1B, each of the dam patterns has the closed-line shape, however, embodiments according to the present disclosure are not limited thereto or thereby. The dam pattern DMP will be described in more detail later with reference to FIG. 5. FIG. 2 is a plan view of the first display substrate 100 according to some

embodiments of the present disclosure. The first display substrate 100 may include signal lines SL1 to SLn and DL1 to DLm and pixels PX11 to PXnm. The signal lines SL1 to SLn and DL1 to DLm may include a plurality of scan lines SL1 to SLn and a plurality of data lines DL1 to DLm. Each of the pixels PX11 to PXnm may be connected to a corresponding scan line of the scan lines SL1 to SLn and a corresponding data line of the data lines DL1 to DLm.

Each of the pixels PX11 to PXnm may include a pixel driving circuit and a light emitting element. More types of signal lines may be provided in the first display substrate 100 depending on the configuration of the pixel driving circuit of the pixels PX11 to PXnm.

A gate driving circuit GDC may be integrated in the first display substrate 100 through an oxide silicon gate driver circuit (OSG) process or an amorphous silicon gate driver circuit (ASG) process. The gate driving circuit GDC connected to the gate lines SL1 to SLn may be located in one side of the non-display area NDA in the first direction DR1. Pads PD connected to ends of the data lines DL1 to DLm may be located in one side of the non-display area NDA in the second direction DR2.

As shown in FIG. 3, the unit pixels PXU may be arranged in the first direction DR1 and the second direction DR2. In the present embodiments, the unit pixel PXU may include the first pixel area PXA-R, the second pixel area PXA-G, and the third pixel area PXA-B, which emit lights having different colors from each other. The first pixel area PXA-R, the second pixel area PXA-G, and the third pixel area PXA-B may emit a red light, a green light, and a blue light, respectively.

The first pixel area PXA-R, the second pixel area PXA-G, and the third pixel area PXA-B may be defined with respect to the second display substrate 200. A peripheral area NPXA may be defined between the first, second, and third pixel areas PXA-R, PXA-G, and PXA-B. The peripheral area NPXA may define a boundary of the first, second, and third pixel areas PXA-R, PXA-G, and PXA-B and may prevent or reduce a color mixture between the first, second, and third pixel areas PXA-R, PXA-G, and PXA-B.

Among the pixels PX11 to PXnm (refer to FIG. 2) of the first display substrate 100 (refer to FIG. 2), a pixel overlapping the first pixel area PXA-R of the second display substrate 200 may be defined as a first pixel, a pixel overlapping the second pixel area PXA-G of the second display substrate 200 may be defined as a second pixel, and a pixel overlapping the third pixel area PXA-B of the second display substrate 200 may be defined as a third pixel. However, as described later, the first pixel, the second pixel, and the third pixel may have substantially the same configuration without being distinguished from each other. The first pixel, the second pixel, and the third pixel may be merely defined as the pixels respectively overlapping the first pixel area PXA-R, the second pixel area PXA-G, and the third pixel area PXA-B without being distinguished from each other.

Each of the first pixel, the second pixel, and the third pixel may include a light emitting element OLED (refer to FIG. 4), the light emitting elements OLED (refer to FIG. 4) of the first pixel, the second pixel, and the third pixel may emit the source lights having the same color. However, the light emitting elements OLED (refer to FIG. 4) of the first pixel, the second pixel, and the third pixel may have the same size as each other or different sizes from each other.

The source lights generated by the light emitting elements OLED (refer to FIG. 4) of the first pixel, the second pixel, and the third pixel may be converted to lights having different colors from each other while passing through the first pixel area PXA-R, the second pixel area PXA-G, and the third pixel area PXA-B. The source light generated by the first display substrate 100 may be converted to the light having different color in the second display substrate 200 described later.

Referring to FIG. 3, the first pixel area PXA-R and the third pixel area PXA-B may be arranged in the same row, and the second pixel area PXA-G may be arranged in a row different from the row in which the first pixel area PXA-R and the third pixel area PXA-B are arranged. The second pixel area PXA-G may have the largest size, and the third pixel area PXA-B may have the smallest size, however, embodiments according to the present disclosure are not limited thereto or thereby. According to some embodiments, each of the first pixel area PXA-R, the second pixel area PXA-G, and the third pixel area PXA-B has a substantially square shape, however, the arrangement and size of the pixel areas should not be particularly limited.

The arrangement of the first pixel area PXA-R, the second pixel area PXA-G, and the third pixel area PXA-B located in the unit pixels PXU shown in FIG. 3 is merely one example, however, the present disclosure should not be limited thereto or thereby. According to some embodiments, the first pixel area PXA-R, the second pixel area PXA-G, and the third pixel area PXA-B may be arranged in the same row along the first direction DR1. In addition, arrangements of the first pixel area PXA-R, second pixel area PXA-G, and third pixel area PXA-B of the unit pixels PXU are not necessarily the same as each other.

Hereinafter, the cross-sectional structure of the first display substrate 100 and the second display substrate 200 in the first pixel area PXA-R will be described with reference to FIG. 4.

The first display substrate 100 may include a first base layer BS1, a circuit layer 100-CL, a display element layer 100-OLED, an encapsulation layer TFE, and a light control layer CFL.

The first base layer BS1 may be located at a lowermost position of the first display substrate 100. The first base layer BS1 may provide a space in which components except the first base layer BS1 included in the first display substrate 100 are stacked.

The first base layer BS1 may include a synthetic resin layer or a glass layer. The first base layer BS1 may include a first synthetic resin layer, a second synthetic resin layer, and an inorganic layer located between the first and second synthetic resin layers. The synthetic resin layer may include a heat curable resin. Particularly, the synthetic resin layer may be a polyimide-based resin layer, however, it should not be limited thereto or thereby. The synthetic resin layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, or a perylene-based resin.

A light blocking layer BML may be located on the first base layer BS1. The light blocking layer BML may block an external light traveling to the display device DD in a direction opposite to the third direction DR3. The light blocking layer BML may include a metal material. A signal line may be located on the same layer as the light blocking layer BML. A first insulating layer 10 may be located on the light blocking layer BML.

A semiconductor pattern may be located on the first insulating layer 10 and may overlap the light blocking layer BML. The semiconductor pattern may include a first region having a relatively high conductivity and a second region having a relatively low conductivity. The semiconductor pattern may have different doping concentrations depending on their regions, and the doping concentration may determine electrical properties of the semiconductor pattern. The first region may be doped with an N-type dopant or a P-type dopant. A P-type transistor may include a doped region doped with the P-type dopant, and an N-type transistor may include a doped region doped with the N-type dopant. The second region may be a non-doped region or a region doped at a concentration lower than that of the first region.

A second insulating layer 20 may be located on the first insulating layer 10. A first contact hole CNT1 may be defined through upper and lower surfaces of the second insulating layer 20. The semiconductor pattern may include a source area SA1, a channel area CA1, and a drain area DA1. The source area SA1 and the drain area DA1 may be exposed through the first contact hole CNT1. Each of the first insulating layer 10 and the second insulating layer 20 may be an inorganic layer.

A gate electrode G1 and connection electrodes CNE1 and CNE2 may be located on the second insulating layer 20. A first connection electrode CNE1 may electrically connect the source area SA1 of the first transistor T1 to a drain or a source of other transistors included in the pixel circuit. A second connection electrode CNE2 may electrically connect the drain area DA1 of the first transistor T1 to other transistor included in the pixel circuit or signal lines.

A third insulating layer 30 may be located on the second insulating layer 20, and a third connection electrode CNE3 may be located on the third insulating layer 30. A second contact hole CNT2 may be defined through upper and lower surfaces of the third insulating layer 30. The third connection electrode CNE3 may be connected to the first connection electrode CNE1 via the second contact hole CNT2.

A fourth insulating layer 40 may be located on the third insulating layer 30. A first electrode AE may be located on the fourth insulating layer 40. In the present embodiments, the first electrode AE will be described as an anode AE. A third contact hole CNT3 may be defined through upper and lower surfaces of the fourth insulating layer 40. The anode AE may be connected to the third connection electrode CNE3 via the third contact hole CNT3. Each of the third insulating layer 30 and the fourth insulating layer 40 may be an organic layer.

The light emitting element OLED and a pixel definition layer PDL may be located on the fourth insulating layer 40. The pixel definition layer PDL may be provided with an opening PDL-OP defined therethrough. At least a portion of the anode AE may be exposed through the opening PDL-OP of the pixel definition layer PDL. An area in which the pixel definition layer PDL is located may be defined as a non-light-emitting area. The opening PDL-OP of the pixel definition layer PDL may be defined as the light emitting area.

A hole control layer HCL, a light emitting layer EML, and an electron control layer ECL may be defined as a common layer. In the present disclosure, the common layer may be entirely arranged in the display area DA (refer to FIG. 1C) and the non-light-emitting area NDA (refer to FIG. 1C). In addition, the common layer may commonly overlap the plural unit pixels PXU (refer to FIG. 3).

The hole control layer HCL may be commonly arranged in the light emitting area and the non-light-emitting area.

The electron control layer ECL may be located on the light emitting layer EML. The electron control layer ECL may include an electron transport layer and an electron injection layer. A second electrode CE may be located on the electron control layer ECL. In the present embodiments, the second electrode CE will be described as a cathode CE.

The encapsulation layer TFE may be located on a lower surface of the light control layer CFL. The encapsulation layer TFE may be commonly arranged on the unit pixels PXU (refer to FIG. 3). The encapsulation layer TFE may prevent or reduce instances of external moisture, contaminants, and/or oxygen entering the light emitting layer EML and may prevent or reduce deterioration of the reliability of the display device DD. The encapsulation layer TFE may include a first inorganic layer LIL, a first organic layer OL1, and a second inorganic layer UIL, however, embodiments according to the present disclosure are not limited thereto or thereby. According to some embodiments, the encapsulation layer TFE may further include a plurality of inorganic layers and a plurality of organic layers.

The first inorganic layer LIL may be located on the second electrode CE. The first inorganic layer LIL may prevent or reduce instances of external moisture, contaminants, and/or oxygen entering the light emitting layer EML. The first inorganic layer LIL may include silicon nitride, silicon oxide, or a compound thereof. The first inorganic layer LIL may be formed through a deposition process.

The first organic layer OL1 may be located on the first inorganic layer LIL. The first organic layer OL1 may provide a flat surface on the first inorganic layer LIL. Uneven portions may be formed on the first inorganic layer LIL or particles formed in the manufacturing process of the display panel DP may remain on the first inorganic layer LIL. The first organic layer OL1 may be located on the first inorganic layer LIL, and thus, the first organic layer OL1 may prevent or reduce instances of the uneven portions or particles on the first inorganic layer LIL exerting influences on the components formed on the first organic layer OL1. The first organic layer OL1 may include an organic material and may be formed through a solution process, such as a spin coating process, a slit coating process, an inkjet process, or the like. Because the solution containing the organic material has flowability in the process of forming the first organic layer OL1, an overflow phenomenon in which the first organic layer OL1 is formed beyond the display area DA may occur. The dam patterns DMP may prevent or reduce the occurrence of the overflow phenomenon, and the dam patterns DMP will be described in more detail later with reference to FIG. 5.

The second inorganic layer UIL may be located on the first organic layer OL1 to cover the first organic layer OL1. The second inorganic layer UIL may include silicon nitride, silicon oxide, or a compound thereof. Because the first organic layer OL1 provides the flat surface, the second inorganic layer UIL may be stably formed on a relatively flat surface when compared with a case where the second inorganic layer UIL is located directly on the first inorganic layer LIL. The second inorganic layer UIL may be formed through a deposition process. A hydrogen plasma treatment may be further performed on the first organic layer OL1 between the forming of the first organic layer OL1 and the forming of the second inorganic layer UIL. When the surface of the first organic layer OL1 is hydrogen-plasma treated, the second inorganic layer UIL may be more uniformly formed on the surface of the first organic layer OL1.

The light control layer CFL may be located on the encapsulation layer TFE. The light control layer CFL may include a bank BK, light control patterns CCF-R, CCF-G, and CCF-B, and a capping layer CP.

The bank BK may be provided in plural and may be located on the second inorganic layer UIL. The banks BK may be arranged spaced apart from each other, and separation spaces respectively defined between the banks BK may be defined as openings BK-OP. The openings BK-OP may correspond to the first, second, and third pixel areas PXA-R, PXA-G, and PXA-B. FIG. 4 shows one opening BK-OP overlapping the first pixel area PXA-R as a representative example.

As the banks BK are arranged spaced apart from each other, a barrier wall formed by the light control patterns CCF-R, CCF-G, and CCF-B located between the banks BK and spaced apart from each other. According to some embodiments, the bank BK may be a pattern with a black color, e.g., a black matrix. The bank BK may include a black coloring agent. The black coloring agent may include a black dye or a black pigment. According to some embodiments, the black coloring agent may include a metal material, such as carbon black, chromium, or an oxide thereof.

The first, second, and third light control patterns CCF-R, CCF-G, and CCF-B may be located in the openings BK-OP, respectively. The first, second, and third light control patterns CCF-R, CCF-G, and CCF-B may convert the optical properties of the source light. In detail, the first and second light control patterns CCF-R and CCF-G may absorb the source light and may generate a light having a color different from that of the source light. The third light control pattern CCF-B may transmit or scatter a portion of the source light incident thereto. Accordingly, the light exiting through the third light control pattern CCF-B may have substantially the same color as that of the source light. As described above, the third light control pattern CCF-B may have an optical function different from that of the first and second light control patterns CCF-R and CCF-G.

Each of the first and second light control patterns CCF-R and CCF-G may include a base resin and quantum dots mixed with (or dispersed in) the base resin. The first and second light control patterns CCF-R and CCF-G may be defined as a quantum dot pattern and may include different quantum dots. The base resin may be a medium in which the quantum dots are dispersed, and may include various resin compositions that are generally referred to as a binder, however, it should not be limited thereto or thereby. In the present disclosure, any medium in which the quantum dots are dispersed may be referred to as the base resin regardless of its name, additional functions, constituent materials, etc. The base resin may be a polymer resin. For example, the base resin may be an acrylic-based resin, a urethane-based resin, a silicone-based resin, or an epoxy-based resin. The base resin may be a transparent resin.

The quantum dots may be particles that change a wavelength of light incident thereto. The quantum dots are a material having a crystal structure of several nanometers in size, contain hundreds to thousands of atoms, and exhibit a quantum confinement effect in which an energy band gap increases due to a small size. When a light having a wavelength with an energy higher than the band gap is incident into the quantum dots, the quantum dots absorb the light and become excited, and then, the quantum dots emit a light of a specific wavelength and fall to a ground state. The emitted light of the specific wavelength has an energy value corresponding to the band gap. The light-emitting property of the quantum dots due to the quantum confinement effect may be controlled by adjusting the size and the composition of the quantum dots. According to some embodiments, the diameter of the quantum dot may be within a range of 1 nanometer (nm) to 10 nm (or about 1 nm to about 10 nm).

The quantum dots may be synthesized by a wet chemical process, a metal organic chemical vapor deposition process, a molecular beam epitaxy process, or similar processes. The wet chemical process is a method of growing quantum dot particle crystals after mixing an organic solvent with a precursor material. When the crystals grow, the organic solvent may naturally serve as a dispersant coordinated to the surface of the quantum dot crystal and may control the growth of the crystals.

Accordingly, the wet chemical process may be easier than vapor deposition methods such as the metal organic chemical vapor deposition process or the molecular beam epitaxy and may control the growth of quantum dot particles through a low-cost process.

The quantum dots may include a group III-VI compound, a group II-VI compound, a group III-V compound, a group I-III-VI compound, a group IV-VI compound, a group IV element, a group IV compound, or an arbitrary combination thereof.

The group III-VI compound may include a binary compound such as GaS, Ga2S3, GaSe, Ga2Se3, GaTe, InS, InSe, In2Se3, and/or InTe, a ternary compound such as InGaS3 and/or InGaSe3, or an arbitrary combination thereof.

The group II-VI compound may include a binary compound such as CdS, CdSe, CdTe, ZnS, ZnSe, ZnTe, ZnO, HgS, HgSe, HgTe, MgSe, and/or MgS, a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS, a quaternary compound such as CdZnSeS, CdZnSeTe, CdZnSTe, CdHgSeS, CdHgSeTe, CdHgSTe, HgZnSeS, HgZnSeTe, and/or HgZnSTe, or an arbitrary combination thereof. Meanwhile, the group II-VI compound may further include a group I metal and/or a group IV element. The group I-II-VI compound may be selected from CuSnS or CuZnS, and the group II-IV-VI compound may be selected from ZnSnS. The group I-II-IV-VI compound may be selected from a quaternary compound selected from the group consisting of Cu2ZnSnS2, Cu2ZnSnS4, Cu2ZnSnSe4, Ag2ZnSnS2, and a mixture thereof.

The group III-V compound may include a binary compound such as GaN, GaP, GaAs, GaSb, AlN, AlP, AlAs, AlSb, InN, InP, InAs, and/or InSb, a ternary compound such as GaNP, GaNAs, GaNSb, GaPAs, GaPSb, AlNP, AlNAs, AlNSb, AlPAs, AlPSb, InGaP, InNP, InAlP, InNAs, InNSb, InPAs, and/or InPSb, a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and/or InAlPSb, or an arbitrary combination thereof. The group III-V compound may further include a group II element. For instance, the group III-V compound that further includes the group II element may include InZnP, InGaZnP, InAlZnP, etc.

The group I-III-VI compound may include a ternary compound such as AgInS, AgInS2, AgInSe2, AgGaS, AgGaS2, AgGaSe2, CuInS, CuInS2, CuInSe2, CuGaS2, CuGaSe2, CuGaO2, AgGaO2, and/or AgAlO2, a quaternary compound such as AgInGaS2 and/or CuInGaS2, or an arbitrary combination thereof.

The group IV-VI compound may include a binary compound such as SnS, SnSe, SnTe, PbS, PbSe, and/or PbTe, a ternary compound such as SnSeS, SnSeTe, SnSTe, PbSeS, PbSeTe, PbSTe, SnPbS, SnPbSe, and/or SnPbTe, a quaternary compound such as SnPbSSe, SnPbSeTe, and/or SnPbSTe, or an arbitrary combination thereof.

The group II-IV-V compound may include a ternary compound selected from the group consisting of ZnSnP, ZnSnP2, ZnSnAs2, ZnGeP2, ZnGeAs2, CdSnP2, CdGeP2, and a mixture thereof.

The group IV element or the group IV compound may include a single-element compound such as Si or Ge, a binary compound such as SiC or SiGe, and an arbitrary combination thereof.

Each element included in a multi-element compound, such as the binary compound, the ternary compound, or the quaternary compound, may be present in the particles at a uniform or non-uniform concentration. That is, the above chemical formula means the types of elements included in the compound, and an element ratio in the compound may be variable. As an example, AgInGaS2 may mean AgInxGa1-xS2 (x is a real number between 0 to 1).

Meanwhile, the quantum dot may have a single structure in which the concentration of each element in the quantum dot is substantially uniform, or a core-shell dual structure. For example, the material included in the core and the material included in the shell may be different from each other.

The shell of the quantum dot may serve as a protective layer to prevent or reduce chemical modification of the core and to maintain semiconductor properties and/or may serve as a charging layer to impart electrophoretic properties to the quantum dot. The shell may have a single-layer or multi-layer structure. The concentration of elements existing in the shell may have the concentration gradient that is lowered as the distance from the center decreases in an interface between the core and the shell. (In the core/shell structure, the concentration of elements existing in the shell may have a concentration gradient that is lowered as the distance from the core decreases in an interface between the core and the shell.)

The shell of the quantum dots may include metal oxides, non-metal oxides, semiconductor compounds, or combinations thereof as its representative example. The metal oxides or non-metal oxides may include a binary compound, such as SiO2, Al2O3, TiO2, ZnO, MnO, Mn2O3, Mn3O4, CuO, FeO, Fe2O3, Fe3O4, CoO, Co3O4, and NiO, a ternary compound, such as MgAl2O4, CoFe2O4, NiFe2O4, and CoMn2O4, or an arbitrary combination thereof. The compounds may include the group III-VI compound, the group II-VI compound, the group III-V compound, the group I-III-VI compound, the group IV-VI compound, or an arbitrary combination thereof. As an example, the compounds may include CdS, CdSe, CdTe, ZnS, ZnSe, ZnTe, ZnSeS, ZnTeS, GaAs, GaP, GaS, GaSe, AgGaS, AgGaS2, GaSb, HgS, HgSe, HgTe, InAs, InP, InGaP, InSb, AlAs, AlP, AlSb, or an arbitrary combination thereof.

Each element included in a multi-element compound, such as the binary compound, or the ternary compound, may be present in the particles at a uniform or non-uniform concentration. That is, the above chemical formula means the types of elements included in the compound, and an element ratio in the compound may be variable.

The quantum dots may have a full width of half maximum (FWHM) of a light emission wavelength spectrum of about 45 nm or less, preferably about 40 nm or less, and more preferably about 30 nm or less. The color purity and the color reproducibility may be improved within this range. In addition, because the light emitted through the quantum dots may be emitted in all directions, an optical viewing angle may be improved.

The quantum dots may have a spherical shape, a pyramidal shape, a multi-arm shape, or cubic nanoparticles, nanotubes, nanowires, nanofibers, nanoplatelets, or the like.

Because the energy band gap may be adjusted by controlling the size of the quantum dot or the element ratio in the compounds for the quantum dot, lights having one or more suitable wavelength bands may be obtained from a quantum dot light-emitting layer. Accordingly, as the quantum dots having different sizes are used or the compounds having different element ratios are used, the light emitting element that emits the lights of one or more suitable wavelengths may be implemented. In detail, the size of the quantum dot and the control of the element ratio of the compounds for the quantum dot may be selected to emit the red, green and/or blue lights. In addition, the quantum dot may be configured to emit a white light by combination of the lights having various colors.

According to some embodiments, the first light control pattern CCF-R may be a red quantum dot pattern that absorbs the source light and generates the red light, the second light control pattern CCF-G may be a green quantum dot pattern that absorbs the source light and generates the green light. The first light control pattern CCF-R and the second light control pattern CCF-G may further include scattering particles.

The third light control pattern CCF-B may further include scattering particles mixed with (or dispersed in) the organic material. The third light control pattern CCF-B may be a scattering pattern to scatter the source light. The scattering particles may be particles having a relatively large density or specific gravity. The scattering particles may include titanium oxide (TiO₂) or silica-based nanoparticles.

The capping layer CP may be located on the bank BK and the first, second, and third light control patterns CCF-R, CCF-G, and CCF-B. The capping layer CP may encapsulate the bank BK and the first, second, and third light control patterns CCF-R, CCF-G, and CCF-B to prevent or reduce damage to the bank BK and the first, second, and third light control patterns CCF-R, CCF-G, and CCF-B in the subsequent process. The capping layer CP may have a single-layer or multi-layer structure. The capping layer CP may include silicon oxide, silicon nitride, silicon oxynitride, or the like.

The second display substrate 200 may be located above the first display substrate 100 and may be spaced apart from the first display substrate 100. The cell gap GP may be a space between the first display substrate 100 and the second display substrate 200 spaced apart from the first display substrate 100. The cell gap GP may be maintained in an empty space or may be filled with a gas. In addition, the cell gap GP may be filled with a filling member FM. The filling member FM may include an epoxy-based organic material. FIG. 4 shows the structure in which the cell gap GP is filled with the filling member FM as a representative example.

The second display substrate 200 may include a second base layer BS2, color filters CF-R, CF-G, and CF-B, and an upper cover layer CP-U.

The second base layer BS2 may be located at an uppermost position of the second display substrate 200. The second base layer BS2 may provide a space in which components are stacked except the second base layer BS2 included in the second display substrate 200. The second base layer BS2 may include a synthetic resin layer or a glass layer. The second base layer BS2 may include a first synthetic resin layer, a second synthetic resin layer, and an inorganic layer located between the first and second synthetic resin layers. The synthetic resin layer may include a heat curable resin. The synthetic resin layer may be a polyimide-based resin layer, however, it should not be limited thereto or thereby. The synthetic resin layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, or a perylene-based resin.

The color filters CF-R, CF-G, and CF-B may be located on a lower surface BS2-LS of the second base layer BS2. Referring to FIG. 4, the color filters CF-R, CF-G, and CF-B may include first, second, and third color filters CF-R, CF-G, and CF-B respectively overlapping the first, second, and third pixel areas PXA-R, PXA-G, and PXA-B. The first, second, and third color filters CF-R, CF-G, and CF-B may be a red color filter, a green color filter, and a blue color filter, respectively.

The first pixel area PXA-R, the second pixel area PXA-G, the third pixel area PXA-B, and the peripheral area NPXA may be defined by the first, second, and third color filters CF-R, CF-G, and CF-B, respectively. The peripheral area NPXA may be defined as an area where two or more color filters of the first, second, and third color filters CF-R, CF-G, and CF-B overlap each other. The first pixel area PXA-R may overlap only the first color filter CF-R, the second pixel area PXA-G may overlap only the second color filter CF-G, and the third pixel area PXA-B may overlap only the third color filter CF-B.

When two or more color filters overlap each other, the effect of blocking the external light may increase, and the interference of colors or the color mixture between the pixels may be prevented or reduced. Therefore, the structure in which two or more color filters overlap each other may correspond to a light blocking structure.

A filter opening may be defined through the second color filter CF-G and the third color filter CF-B to correspond to the first pixel area PXA-R. Similarly, a filter opening may be defined through the first color filter CF-R and the third color filter CF-B to correspond to the second pixel area PXA-G, and a filter opening may be defined through the first color filter CF-R and the second color filter CF-G to correspond to the third pixel area PXA-B.

The second display substrate 200 may further include a low refractive index layer LR. The low refractive index layer LR may be located under the color filters CF-R, CF-G, and CF-B and may cover the color filters CF-R, CF-G, and CF-B. The low refractive index layer LR may control a transmittance of the light provided thereto from the light control layer CFL and may improve an efficiency of the light visible to the outside.

The second display substrate 200 may further include the upper cover layer CP-U. The upper cover layer CP-U may be located on a lower surface of the low refractive index layer LR. The low refractive index layer LR may be omitted from the second display substrate 200. In this case, the upper cover layer CP-U may be directly in contact with the first, second, and third color filters CF-R, CF-G, and CF-B. The upper cover layer CP-U may serve as a protective layer that covers the color filters CF-R, CF-G, and CF-B and prevents or reduces damage to the color filters CF-R, CF-G, and CF-B in the manufacturing process of the display device DD. The upper cover layer CP-U may be omitted from the second display substrate 200.

The second display substrate 200 may further include a step-difference compensation layer. The step-difference compensation layer may be located on the lower surface of the upper cover layer CP-U overlapping the non-display area NDA. The step-difference compensation layer may compensate for a step difference occurring in the second display substrate 200 during processes of forming the first, second, and third color filters CF-R, CF-G, and CF-B and the upper cover layer CP-U. Accordingly, the sealing member SLM (refer to FIG. 1C) may be located on the flat surface provided by the step-difference compensation layer, and thus, the second display substrate 200 and the first display substrate 100 may be bonded with each other through a vacuum-pressure process.

Hereinafter, a display device DD will be described with reference to FIG. 5. In FIG. 5, the same/similar reference numerals denote the same/similar elements in FIG. 4, and thus, detailed descriptions of the same elements will be omitted.

The display device DD may include a first display substrate 100 and a second display substrate 200. The first display substrate 100 and the second display substrate 200 may be spaced apart from each other with a sealing member SLM interposed therebetween. A filling member FM may be filled in between the first display substrate 100 and the second display substrate 200. The filling member FM may cover a capping layer CP.

The first display substrate 100 may include a first base layer BS1, a circuit layer 100-CL, a display element layer 100-OLED, an encapsulation layer TFE, a light control layer CFL, dam patterns DMP, and a second organic layer OL2.

Description about the first base layer BS1, the circuit layer 100-CL, the display element layer 100-OLED, the encapsulation layer TFE, and the light control layer CFL may correspond to those described with reference to FIG. 4.

The dam patterns DMP may be located in a non-display area NDA and may surround at least a portion of the display area DA. A boundary of the first organic layer OL1 may be defined by one of the dam patterns DMP. As an example, referring to FIG. 5, a solution containing an organic material to form the first organic layer OL1 may be coated only up to an inner side of a second dam pattern D2 among the dam patterns DMP. Accordingly, the first organic layer OL1 may be formed only to the inside of the second dam pattern D2, and the boundary of the first organic layer OL1 may be defined by a position of the second dam pattern D2 when viewed in the plane, however, the present disclosure should not be limited thereto or thereby.

The dam patterns DMP may prevent or reduce instances of an organic material, which is used to form the first organic layer OL1, overflowing to the outside of the dam patterns DMP in a process of manufacturing the display device DD.

The dam patterns DMP may have a single-layer or multi-layer structure. As an example, in FIG. 5, a first dam pattern D1 may have the single-layer structure, a second dam pattern D2 may have the multi-layer structure of a first part D2-1 and a second part D2-2 located on the first part D2-1, a third dam pattern D3 may have the multi-layer structure of a first part D3-1 and a second part D3-2 located on the first part D3-1, and a fourth dam pattern D4 may have the multi-layer structure of a first part D4-1 and a second part D4-2 located on the first part D4-1. However, the layer structure of each of the dam patterns DMP should not be limited thereto or thereby as long as the solution containing the organic material does not overflow.

Each of the dam patterns DMP may include the same material as one of the insulating layers included in the display element layer 100-OLED described with reference to FIG. 4.

The first inorganic layer LIL and the second inorganic layer UIL may cover a portion of the upper surface and a portion of the side surface of the dam pattern DMP, respectively. Accordingly, at least a portion of the dam pattern DMP may be covered by the first inorganic layer LIL. As an example, FIG. 5 shows the structure in which an upper surface and a side surface of the third dam pattern D3 are entirely covered by the first inorganic layer LIL and the second inorganic layer UIL and an upper surface and a side surface of the fourth dam pattern D4 are partially covered by the first inorganic layer LIL and the second inorganic layer UIL.

The first inorganic layer LIL and the second inorganic layer UIL may be at least partially in contact with each other in the non-display area NDA. As an example, referring to FIG. 5, the first inorganic layer LIL may be located on the fourth dam pattern D4 in the non-display area NDA, and the second inorganic layer UIL may be located on the first inorganic layer LIL in the non-display area NDA. Accordingly, the first inorganic layer LIL and the second inorganic layer UIL may be in contact with each other in the non-display area NDA.

The second organic layer OL2 may be located between the second inorganic layer UIL and the capping layer CP in the non-display area NDA. As the second organic layer OL2 is located between the second inorganic layer UIL and the capping layer CP, an end CP-E of the capping layer and an end UIL-E of the second inorganic layer may be spaced apart from each other with the second organic layer OL2 interposed therebetween in the non-display area NDA.

The second organic layer OL2 may cover the end UIL-E of the first inorganic layer and an end LIL-E of the second inorganic layer, which are located in the non-display area NDA and face the sealing member SLM. In addition, the second organic layer OL2 may cover a portion of the upper surface of the fourth dam pattern D4, which is exposed by the first and second inorganic layers LIL and UIL, and a portion of the side surface of the fourth dam pattern D4, which is adjacent to the sealing member SLM.

The second organic layer OL2 may be spaced apart from the sealing member SLM, however, it should not be limited thereto or thereby. According to some embodiments, the second organic layer OL2 may be in contact with the sealing member SLM or may be partially arranged between the sealing member SLM and the first base layer BS1.

The capping layer CP may cover a portion of the second organic layer OL2. Referring to FIG. 5, the capping layer CP may cover a portion of an upper surface OL2-T of the second organic layer only and may not cover a side surface OL2-S of the second organic layer. The upper surface OL2-T of the second organic layer may be defined as a portion of the second organic layer OL2, which faces the second display substrate 200, and the side surface OL2-S of the second organic layer OL2 may be defined as a portion of the second organic layer OL2, which faces the sealing member SLM.

The second organic layer OL2 may include the same material as one of the light control patterns CCF-R, CCF-G, and CCF-B. As an example, the second organic layer OL2 may include the same material as the third light control pattern CCF-B. Accordingly, the second organic layer OL2 and the third light control pattern CCF-B may include scattering particles mixed with (or dispersed in) the organic material. The scattering particles may be particles having a relatively large density or specific gravity. The scattering particles may include titanium oxide (TiO₂) or silica-based nanoparticles.

Because the quantum dot is relatively expensive among materials for the light control patterns CCF-R, CF-G, and CCF-B, a case where the second organic layer OL2 includes the same material as the light control pattern that does not include the quantum dot may be more economical than a case where the second organic layer OL2 includes the same material as the light control pattern that includes the quantum dot.

Because the second organic layer OL2 includes the organic material, the second organic layer OL2 may have more flexible characteristics than the inorganic material for the first inorganic layer LIL and the second inorganic layer UIL. Accordingly, as the organic layer is located between the first inorganic layer LIL and the second inorganic layer UIL, the second organic layer OL2 may reduce impacts transferred to the inside of the display device DD.

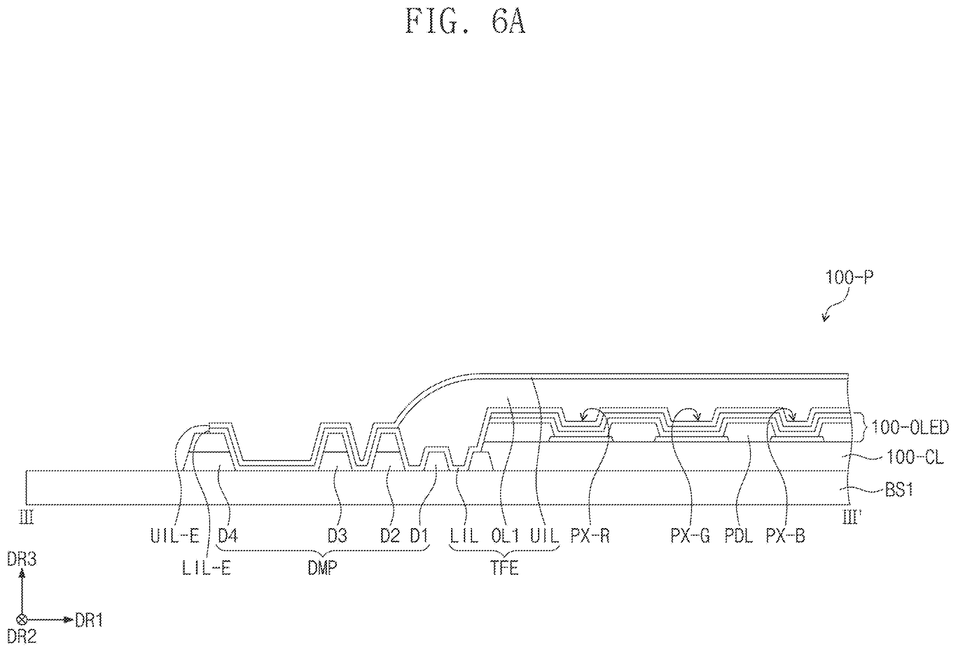

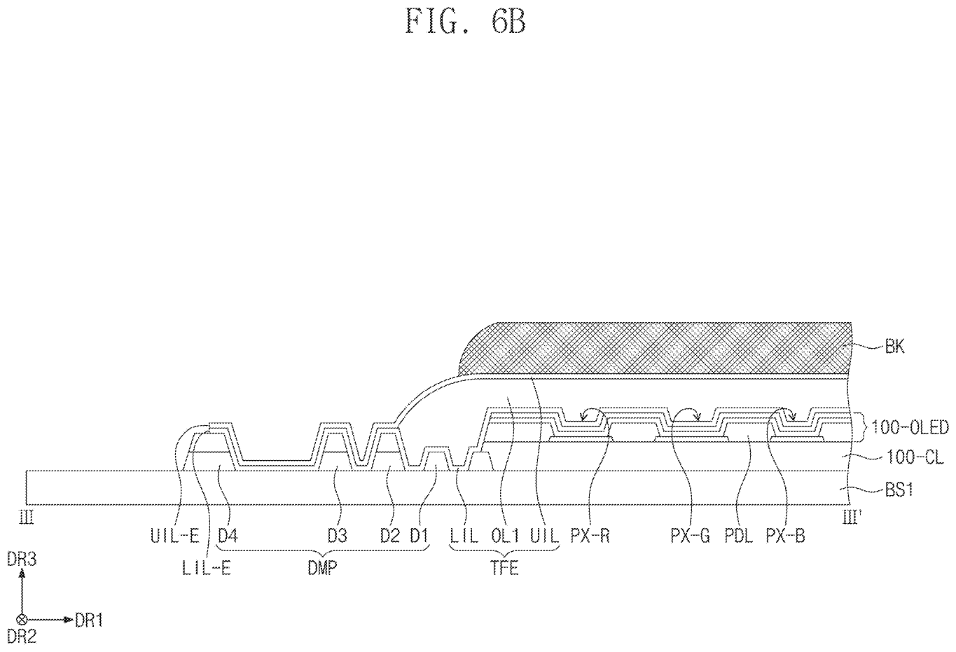

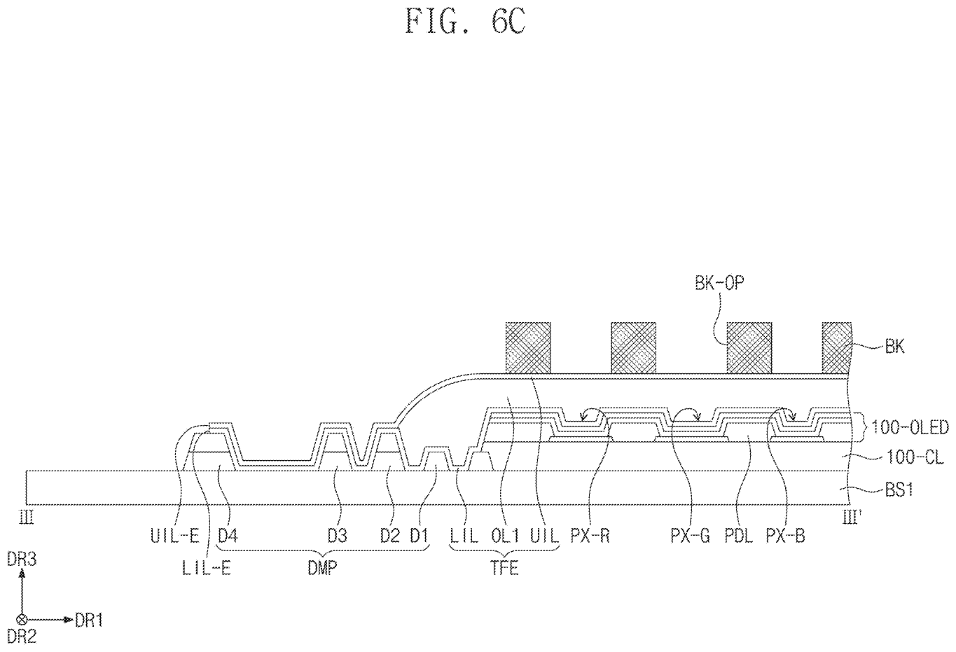

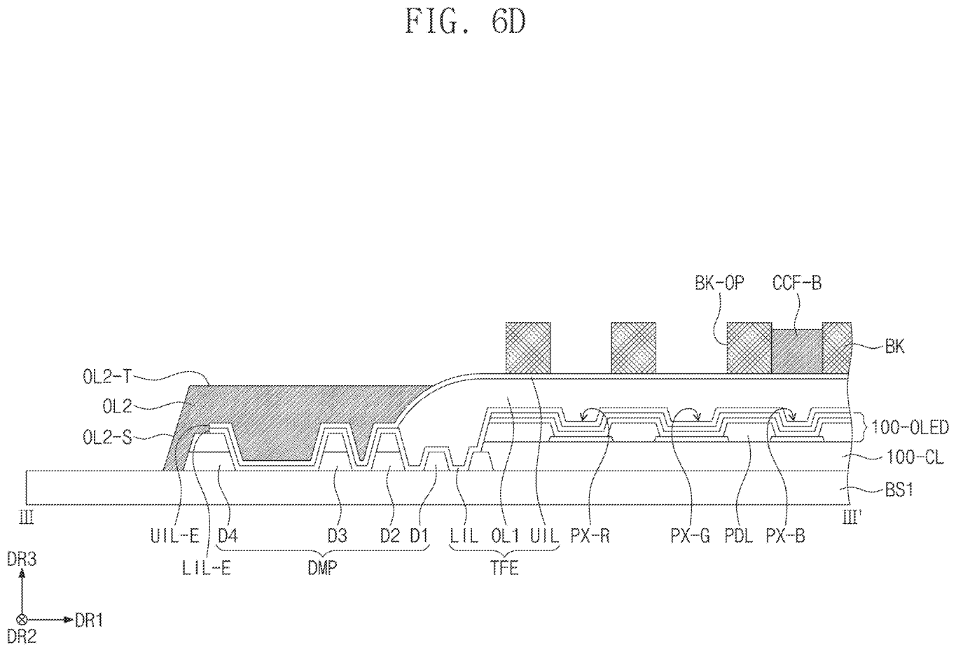

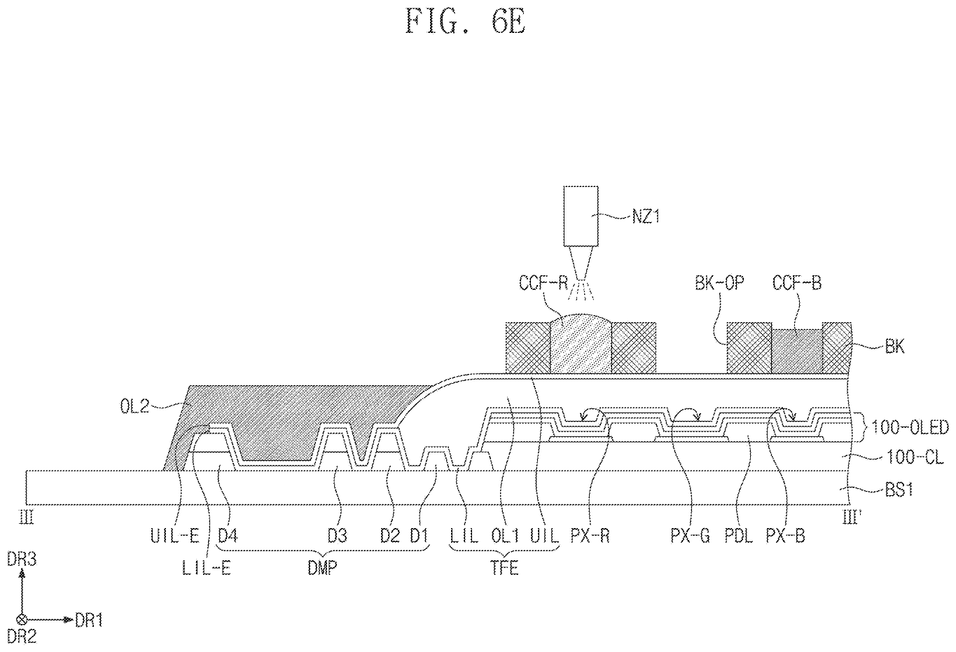

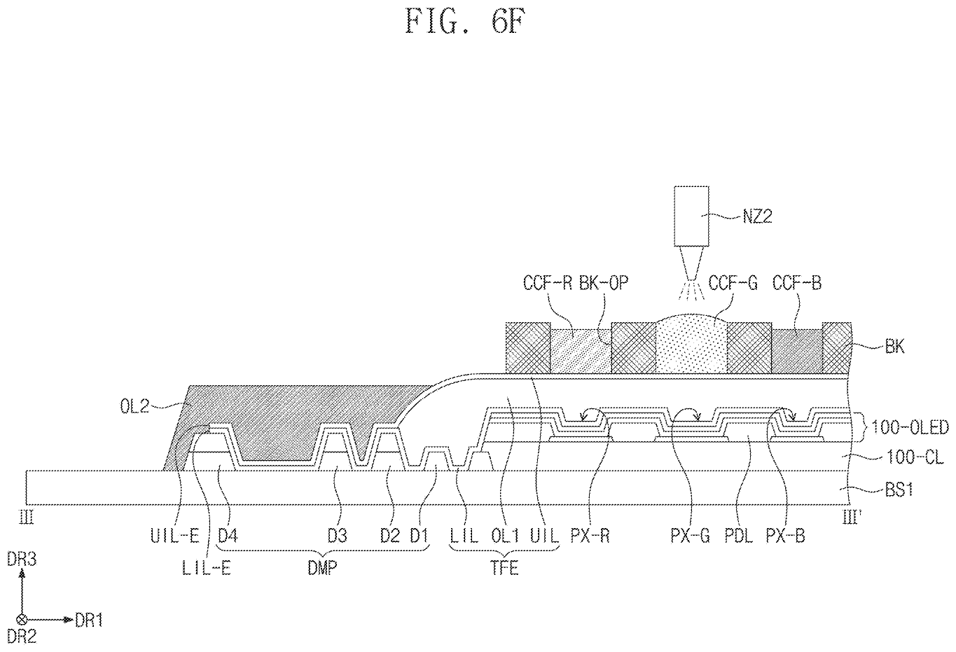

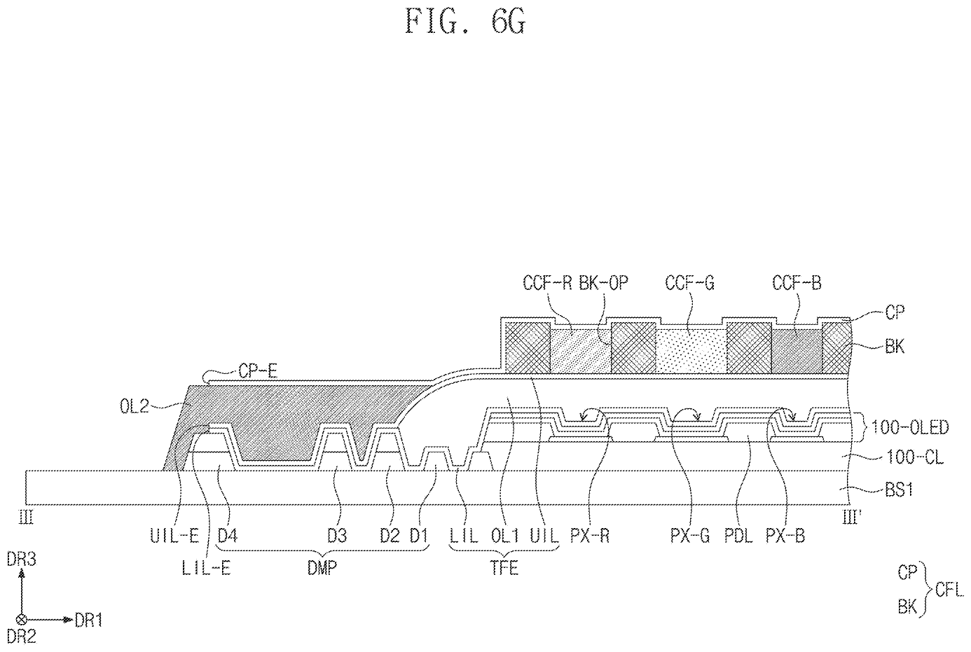

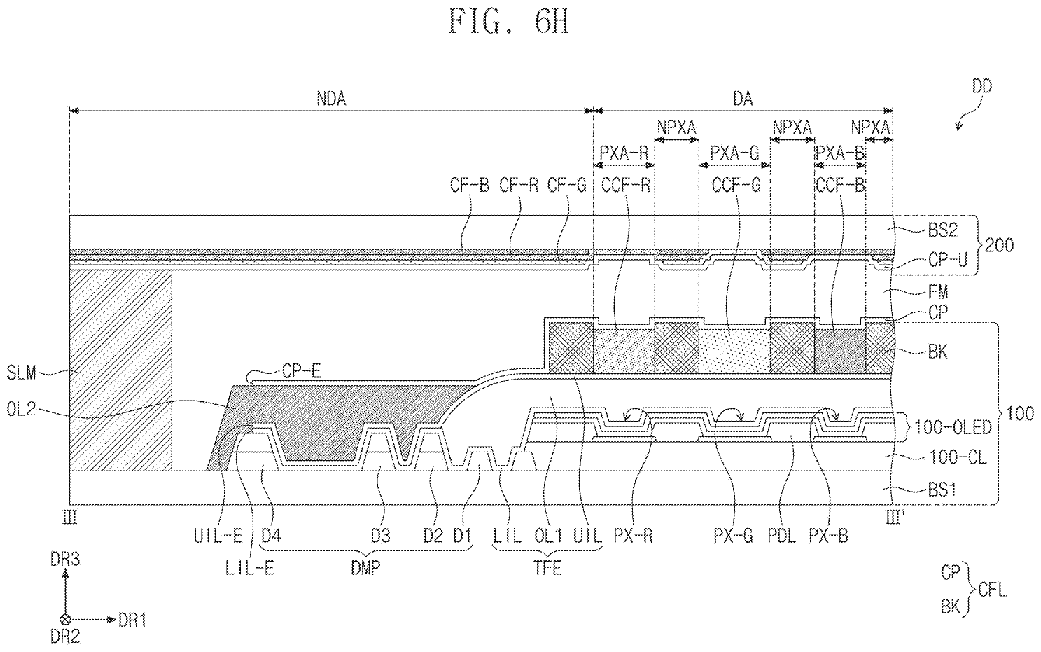

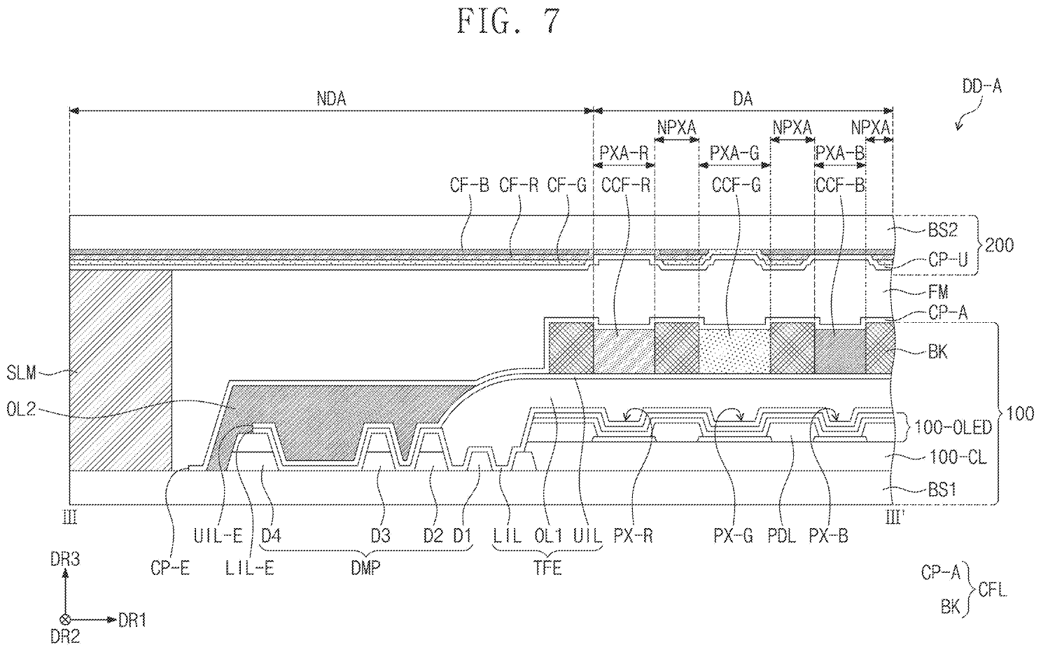

According to some embodiments, the upper surface OL2-T of the second organic layer may be flat. When the upper surface OL2-T of the second organic layer OL2 is flat, the capping layer CP may be deposited more evenly than when the upper surface OL2-T of the second organic layer OL2 is curved. In addition, because the second organic layer OL2 serves as a mask supporter of the open mask used to form the capping layer CP, a deposition process may be simplified. This will be described in detail with reference to FIGS. 6A to 6H.

The end LIL-E of the first inorganic layer, the end UIL-E of the second inorganic layer, and the end CP-E of the capping layer may be aligned with each other in the third direction DR3. This structure may be formed by performing the deposition process using a substantially identical open mask and will be described with reference to FIGS. 6A to 6H.

The second organic layer OL2 and the banks BK may be arranged spaced apart from each other. In this case, a first contact area CP-L1 may be defined in an area between the second organic layer OL2 and the banks BK, and the capping layer CP may be in contact with the second inorganic layer UIL in the first contact area CP-L1. However, because the first organic layer OL1 is located under the first contact area CP-L1, moisture and oxygen permeated through the capping layer CP may be sufficiently prevented from permeating to the light emitting layer EML (refer to FIG. 4).

Different from the present disclosure, in a case where the first inorganic layer LIL, the second inorganic layer UIL, and the capping layer CP are in contact with each other in the non-display area NDA, moisture and oxygen permeated through the capping layer CP may permeate to the light emitting layer EML (refer to FIG. 4). As a result, the property of the light emitting layer EML (refer to FIG. 4) may be changed, so the reliability of the display device DD may be deteriorated.

According to the present disclosure, as the second organic layer OL2 is located between the second inorganic layer UIL and the capping layer CP, the second inorganic layer UIL may be spaced apart from the capping layer CP. Accordingly, the area where the second inorganic layer UIL is directly in contact with the capping layer CP decreases, and thus, moisture, contaminants, and/or oxygen may be prevented from permeating to the light emitting layer EML. The end CP-E of the capping layer and the end UIL-E of the second inorganic layer may be spaced apart from each other with the second organic layer OL2 interposed therebetween.

FIGS. 6A to 6H are cross-sectional views illustrating a method of manufacturing a display device according to some embodiments of the present disclosure. In FIGS. 6A to 6H, the similar/same reference numerals denote the similar/same elements in FIGS. 4 and 5, and thus, detailed descriptions of the same elements will be omitted. The display device manufactured by the manufacturing method described with reference to FIGS. 6A to 6H may correspond to the display device described with reference to FIG. 5.

Referring to FIG. 6A, the manufacturing method of the display device may include providing a work substrate 100-P.

In the present disclosure, the work substrate 100-P may be provided in a state in which the first base layer BS1, the circuit layer 100-CL, the display element layer 100-OLED, and the encapsulation layer TFE included in the first display substrate 100 described in FIG. 5 are formed.

The work substrate 100-P may include first, second, and third pixels PX-R, PX-G, and PX-B located on the first base layer BS1. Each of the first, second, and third pixels PX-R, PX-G, and PX-B may include the transistor T1 (refer to FIG. 4) included in the circuit layer 100-CL and the light emitting element OLED (refer to FIG. 4) connected to the transistor T1 (refer to FIG. 4).

The dam pattern DMP including the layer including the same material as at least one of the insulating layers included in the circuit layer 100-CL may be formed on the first base layer BS1. The dam pattern DMP may be provided in plural. As an example, FIG. 6A shows the first, second, third, and fourth dam patterns D1, D2, D3, and D4 in order of distance from the pixels PX-R, PX-G, and PX-B.

The encapsulation layer TFE may include the first inorganic layer LIL, the first organic layer OL1, and the second inorganic layer UIL. The first inorganic layer LIL may cover the pixels PX-R, PX-G, and PX-B.

In the process of forming the first organic layer OL1, the solution containing the organic material may be coated up to the inner side of the second dam pattern D2 of the dam patterns DMP. Accordingly, the boundary of the first organic layer OL1 when viewed in the plane may be determined according to the position of the second dam pattern D2.

The first inorganic layer LIL and the second inorganic layer UIL may be formed in specific areas of the first base layer BS1 by a chemical vapor deposition (CVD) using an open mask. FIG. 6A shows the structure in which the first inorganic layer LIL and the second inorganic layer UIL cover the first, second, and third dam patterns D1, D2, and D3 and cover the portion of the fourth dam pattern D4 as a representative example.

According to some embodiments, the first inorganic layer LIL and the second inorganic layer UIL may be formed using the same open mask. In the process of forming the first mask UIL and the second mask LIL, the open mask open mask may be mounted on some of the dam patterns DMP. In the case where the first inorganic layer LIL and the second inorganic layer UIL are formed using the same open mask, the end LIL-E of the first inorganic layer and the end UIL-E of the second inorganic layer may be aligned with each other in the third direction DR3. The end LIL-E of the first inorganic layer LIL and the end UIL-E of the second inorganic layer

UIL may be located on the upper surface of the fourth dam pattern D4 and may cover the portion of the upper surface of the fourth dam pattern D4, and the other portion of the upper surface of the fourth dam pattern D4 may be exposed without being covered by the end LIL-E of the first inorganic layer LIL and the end UIL-E of the second inorganic layer UIL.

Referring to FIG. 6B, the manufacturing method of the display device may include forming the bank BK. The bank BK may be formed by coating a material containing a black coloring agent on the second inorganic layer UIL. The black coloring agent may include a black dye or a black pigment. The black coloring agent may include a metal material, such as carbon black, chromium, or an oxide thereof.

In the forming of the bank BK, the solution containing the organic material may be coated on the second inorganic layer UIL formed on the flat surface provided by the first organic layer OL1. FIG. 6B shows the structure in which the solution containing the organic material is coated mainly on the upper surface of the second inorganic layer UIL formed on the flat surface provided by the first organic layer OL1 as a representative example.

Referring to FIG. 6C, the manufacturing method of the display device may include etching the bank BK. The openings BK-OP may be formed by removing portions of the bank BK, which overlap the light emitting layer EML (refer to FIG. 4) included in each of the pixels PX-R, PX-G, and PX-B. According to some embodiments, the openings BK-OP may have different widths each other.

According to some embodiments, an angle between the side surface and the lower surface of the bank BK, which defined the openings BK-OP is vertical, however, it should not be limited thereto or thereby. According to some embodiments, the angle between the side surface and the lower surface of the bank BK may be an acute angle.

Referring to FIG. 6D, the manufacturing method of the display device may include forming the third light control pattern CCF-B and forming the second organic layer OL2. According to the present disclosure, the forming of the third light control pattern CCF-B and the forming of the second organic layer OL2 may be performed through the same process.

The third light control pattern CCF-B and the second organic layer OL2 may be formed through a photolithography process, however, the present disclosure should not be limited thereto or thereby. According to some embodiments, the third light control pattern CCF-B and the second organic layer OL2 may be formed through an inkjet process. In the photolithography process to form the third light control pattern CCF-B and the second organic layer OL2, a material for the third light control pattern CCF-B and a material for the second organic layer OL2 may include a common material. The common material may be the scattering particles mixed with or dispersed in the organic material. The scattering particles may be particles having a relatively large density or specific gravity. The scattering particles may include titanium oxide (TiO₂) or silica-based nanoparticles.

The third light control pattern CCF-B may be formed in the opening BK-OP (hereinafter, referred to as a third opening) overlapping the third pixel PX-B. The second organic layer OL2 may be formed on the second inorganic layer UIL in the non-display area NDA (refer to FIG. 6H).

Because the third light control pattern CCF-B and the second organic layer OL2 are formed through the same process, the manufacturing process of the display device may be simplified, and a manufacturing cost may be reduced. In addition, as the third light control pattern CCF-B and the second organic layer OL2 do not include the quantum dot, the manufacturing cost may be reduced.

According to some embodiments, the upper surface OL2-T of the second organic layer OL2 formed by the photolithography process may be flat. When the upper surface OL2-T of the second organic layer OL2 is flat, the upper surface OL2-T of the second organic layer OL2 may serve as the mask supporter to support the open mask used to form the capping layer CP (refer to FIG. 6G). The side surface OL2-S of the second organic layer OL2 may be inclined at a direction between the first direction DR1 and the third direction DR3, however, it should not be limited thereto or thereby.

Referring to FIG. 6E, a process of forming the first light control pattern CCF-R may be carried out. The first light control pattern CCF-R may be formed in the opening BK-OP (hereinafter, referred to as a first opening) overlapping the first pixel PX-R.

The first light control pattern CCF-R may be formed by discharging the material that includes the base resin and the quantum dots mixed with (or dispersed in) the base resin to the first opening BK-OP through the inkjet process using a first nozzle NZ1.

The material discharged through the first nozzle NZ1 may correspond to a solution or emulsion state immediately after being discharged. Accordingly, as shown in FIG. 6E, an upper surface of the material discharged to the first opening may have temporarily a curve shape after being discharged from the first nozzle NZ1. However, the material may be discharged may be cured as a time elapses as shown in FIG. 6F.

Referring to FIG. 6F, a process of forming the second light control pattern CCF-G may be carries out. The second light control pattern CCF-G may be formed in the opening BK-OP (hereinafter, referred to as a second opening) overlapping the first pixel PX-G.

The second light control pattern CCF-G may be formed by discharging the material that includes the base resin and the quantum dots mixed with (or dispersed in) the base resin to the second opening through the inkjet process using a second nozzle NZ2.

The material discharged through the second nozzle NZ2 may correspond to a solution or emulsion state immediately after being discharged. Accordingly, as shown in FIG. 6F, an upper surface of the material discharged to the second opening BK-OP may have temporarily a curve shape after being discharged from the second nozzle NZ2. However, the discharged material may be cured as a time elapses as shown in FIG. 6G.

Referring to FIG. 6G, a process of forming the capping layer CP may be carried out. The capping layer CP may cover the banks BK, the light control patterns CCF-R, CCF-G, and CCF-B, the second inorganic layer UIL, and at least a portion of the second organic layer OL2.

The capping layer CP may be formed by the deposition process using the open mask. In a case where the open mask used in the process of forming the capping layer CP is the same as the mask used in the process of forming the first inorganic layer LIL and the second inorganic layer UIL, the end LIL-E of the first inorganic layer, the end UIL-E of the second inorganic layer, and the end CP-E of the capping layer may be aligned with each other in the third direction DR3. In this case, when the upper surface OL2-T of the second organic layer OL2 is flat, the second organic layer OL2 may serve as the mask supporter to support the open mask used to form the capping layer CP.

Referring to FIG. 6H, the manufacturing process of the display device may include bonding the first display substrate 100 with the second display substrate 200. The second display substrate 200 may include the second base layer BS2, the color filters CF-R, CF-G, and CF-B, and the upper cover layer CP-U.

The first display substrate 100 may be vacuum-bonded with the second display substrate 200 using the sealing member SLM. In this case, the sealing member SLM may be located between the first display substrate 100 and the second display substrate 200 to maintain the space (e.g., the set or predetermined space between) the first display substrate 100 and the second display substrate 200. The space (e.g., the set or predetermined space) may be filled with the filling member FM. According to some embodiments, the filling member FM may be in contact with the upper surface and the side surface of the second organic layer OL2, which are exposed without being covered by the capping layer CP.

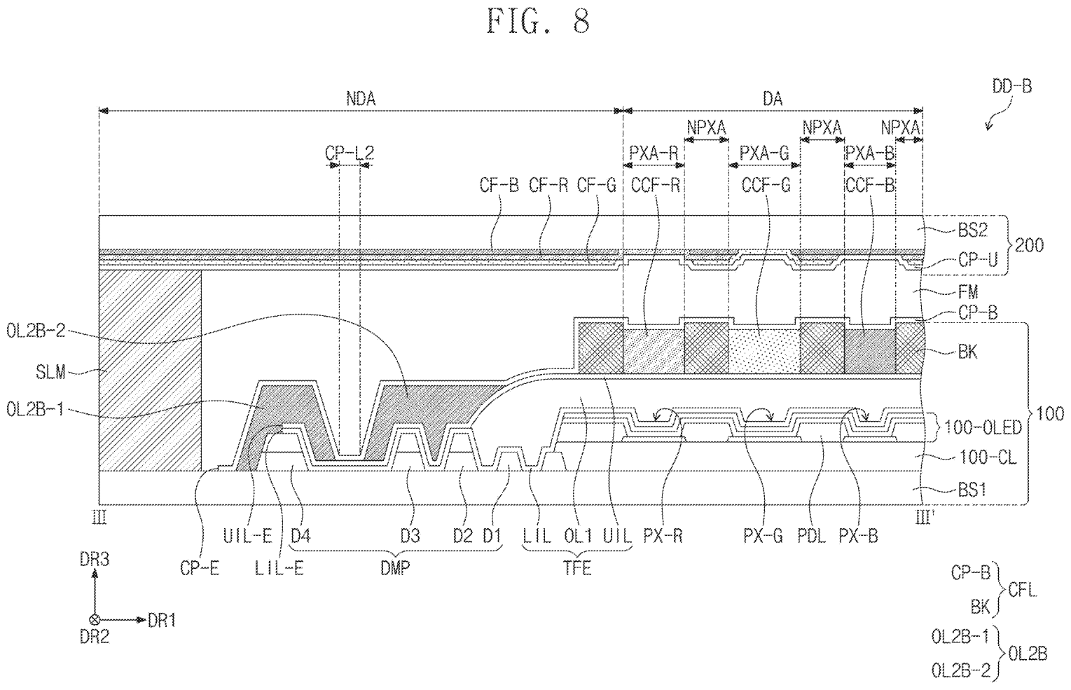

FIG. 7 is a cross-sectional view of a display device DD-A according to some embodiments of the present disclosure. In FIG. 7, the same/similar reference numerals denote the same/similar elements in FIGS. 4 and 5, and thus, detailed descriptions of the same/similar elements will be omitted.

Referring to FIG. 7, the display device DD-A may include a first display substrate 100 and a second display substrate 200. The first display substrate 100 and the second display substrate 200 may be spaced apart from each other with a sealing member SLM interposed therebetween and may be bonded with each other through a vacuum-pressure process. A space between the first display substrate 100 and the second display substrate 200 may be filled with a filling member FM.

The first display substrate 100 may include a first base layer BS1, a circuit layer 100-CL, a display element layer 100-OLED, an encapsulation layer TFE, a light control layer CFL, dam patterns DMP, and a second organic layer OL2. Descriptions of the first base layer BS1, the circuit layer 100-CL, the display element layer 100-OLED, the encapsulation layer TFE, and the light control layer CFL may correspond to the above-descriptions with reference to FIG. 4.

The second display substrate 200 may include a second base layer BS2, color filters CF-R, CF-G, and CF-B, and an upper cover layer CP-U. Descriptions of the second base layer BS2, the color filters CF-R, CF-G, and CF-B, and the upper cover layer CP-U may correspond to the above-descriptions with reference to FIG. 4.

The display device DD-A may include the second organic layer OL2 located in the non-display area NDA and a capping layer CP-A.

According to some embodiments, an upper surface of the second organic layer OL2, a side surface of the second organic layer OL2 adjacent to the sealing member SLM, and a portion of the first base layer BS1 may be covered by the capping layer CP-A.

The capping layer CP-A may be formed by applying the material to form the capping layer CP-A on the first base layer BS1 and performing a photoresist process on a portion except a portion of the capping layer CP-A shown in FIG. 7. Accordingly, because a capping layer CP may not be formed using a mask that is the same as an open mask used to form inorganic layers LIL and UIL, the capping layer CP-A may not be aligned with an end LIL-E of the first inorganic layer and an end UIL-E of the second inorganic layer in the third direction DR3.

Accordingly, an end CP-E of the capping layer may be formed more adjacent to the sealing member SLM than the end LIL-E of the first inorganic layer and the end UIL-E of the second inorganic layer. In addition, the end CP-E of the capping layer may be located at a lower position than the end LIL-E of the first inorganic layer and the end UIL-E of the second inorganic layer in the third direction DR3. As an example, the end CP-E of the capping layer may be located adjacent to the first base layer BS1. FIG. 7 shows the structure in which the end CP-E of the capping layer is formed adjacent to the first base layer BS1.

FIG. 8 is a cross-sectional view of a display device DD-B according to some embodiments of the present disclosure. In FIG. 8, the same/similar reference numerals denote the same/similar elements in FIGS. 4 and 5, and thus, detailed descriptions of the same/similar elements will be omitted.

Referring to FIG. 8, the display device DD-B may include a first display substrate 100 and a second display substrate 200. The first display substrate 100 and the second display substrate 200 may be spaced apart from each other with a sealing member SLM interposed therebetween and may be bonded with each other through a vacuum-pressure process. A space between the first display substrate 100 and the second display substrate 200 may be filled with a filling member FM.

The first display substrate 100 may include a first base layer BS1, a circuit layer 100-CL, a display element layer 100-OLED, an encapsulation layer TFE, a light control layer CFL, dam patterns DMP, and a second organic layer OL2. Descriptions of the first base layer BS1, the circuit layer 100-CL, the display element layer 100-OLED, the encapsulation layer TFE, and the light control layer CFL may correspond to the above-descriptions with reference to FIG. 4.

The second display substrate 200 may include a second base layer BS2, color filters CF-R, CF-G, and CF-B, and an upper cover layer CP-U. Descriptions of the second base layer BS2, the color filters CF-R, CF-G, and CF-B, and the upper cover layer CP-U may correspond to the above-descriptions with reference to FIG. 4.

The display device DD-B may include a second organic layer OL2B located in the non-display area NDA and a capping layer CP-B.

According to some embodiments, a second organic layer OL2B may include a first part OL2B-1 and a second part OL2B-2. The first part OL2B-1 may be covered by the second inorganic layer OL2B and the capping layer CP-B, and at least a portion of the second part OL2B-2 may be covered by the second inorganic layer OL2B and the capping layer CP-B. In addition, the first part OL2B-1 and the second part OL2B-2 may be spaced apart from each other.

As the first part OLB-1 is spaced apart from the second part OL2B-2, a second contact area CP-L2 where the capping layer CP-B is in contact with the second inorganic layer UIL may be defined between the first part OLB-1 and the second part OL2B-2. In this case, because an area where the filling member FM is in contact with the first display substrate 100 increases, a bonding strength between the first display substrate 100 and the second display substrate 200 may increase.

According to some embodiments, because an upper surface of the second organic layer OL2B is required to be entirely covered by the capping layer CP-B, the second organic layer OL2B may not serve as a support for the open mask. Therefore, an end CP-E of the capping layer may not be aligned with ends UIL-E and LIL-E of the inorganic layers in the third direction DR3.

Accordingly, the end CP-E of the capping layer may be formed more adjacent to the sealing member SLM than the end LIL-E of the first inorganic layer and the end UIL-E of the second inorganic layer. In addition, the end CP-E of the capping layer may be located in a lower position than the end LIL-E of the first inorganic layer and the end UIL-E of the second inorganic layer in the third direction DR3. As an example, the end CP-E of the capping layer may be in contact with the first base layer BS1. FIG. 8 shows the structure in which the end CP-E of the capping layer is in contact with the first base layer BS1 as a representative example.

Although aspects of some embodiments of the present disclosure have been described, it is understood that the present disclosure should not be limited to these embodiments but various changes and modifications can be made by one ordinary skilled in the art within the spirit and scope of the present disclosure as hereinafter claimed.

Therefore, the disclosed subject matter should not be limited to any single embodiment described herein, and the scope of embodiments according to the present disclosure shall be determined according to the appended claims, and their equivalents.

What is claimed is:

1. A display device comprising:
a first display substrate comprising a first base layer comprising a display area and a non-display area adjacent to the display area;
a second display substrate spaced apart from the first display substrate and comprising a second base layer comprising pixel areas overlapping the display area and a peripheral area adjacent to the pixel areas and color filters on the second base layer; and
a sealing member between the first display substrate and the second display substrate and overlapping the non-display area, the first display substrate comprising:
light emitting elements respectively overlapping the pixel areas;
an encapsulation layer comprising a first inorganic layer covering the light emitting elements, a second inorganic layer, and a first organic layer between the first inorganic layer and the second inorganic layer;
banks provided with openings defined therethrough to respectively overlap the pixel areas and spaced apart from each other on the encapsulation layer;
light control patterns respectively in the openings;
a capping layer covering the banks and the light control patterns; and
a second organic layer between the second inorganic layer and the capping layer in the non-display area.

2. The display device of claim 1, wherein one light control pattern among the light control patterns comprises a same material as the second organic layer.

3. The display device of claim 2, wherein the material comprises titanium oxide (TiO₂).

4. The display device of claim 3, wherein the other light control patterns except the one light control pattern among the light control patterns comprise a quantum dot.

5. The display device of claim 1, wherein the first inorganic layer and the second inorganic layer are at least partially in contact with each other in the non-display area, and an end of the first inorganic layer and an end of the second inorganic layer, which are in the non-display area and face the sealing member, are covered by the second organic layer.

6. The display device of claim 5, wherein an end of the capping layer, which is in the non-display area and faces the sealing member, is spaced apart from the end of the first inorganic layer and the end of the second inorganic layer with the second organic layer interposed therebetween.

7. The display device of claim 1, wherein the second organic layer is spaced apart from the banks.

8. The display device of claim 1, wherein a portion of an upper surface of the second organic layer and a side surface of the second organic layer adjacent to the sealing member are exposed without being covered by the capping layer.

9. The display device of claim 1, wherein an upper surface of the second organic layer and a side surface of the second organic layer adjacent to the sealing member are covered by the capping layer.

10. The display device of claim 1, wherein an upper surface of the second organic layer is flat.

11. The display device of claim 1, wherein the second organic layer comprises a first part and a second part, the first part is covered by the second inorganic layer and the capping layer, at least a portion of the second part is covered by the second inorganic layer and the capping layer, and the first part is spaced apart from the second part.

12. The display device of claim 1, wherein the first display substrate comprises:
insulating layers on the first display substrate; and
dam patterns in the non-display area and comprising a same material as at least one of the insulating layers.

13. The display device of claim 12, wherein a boundary of the first organic layer is defined by one of the dam patterns, and at least a portion of the dam patterns is covered by the first inorganic layer.

14. The display device of claim 1, wherein the second display substrate comprises:
a low refractive index layer on a lower surface of the color filters to cover the color filters; and
an upper cover layer on a lower surface of the low refractive index layer to cover the low refractive index layer.

15. The display device of claim 1, wherein a separation space between the first display substrate and the second display substrate is filled with a filling member, and the filling member comprises an organic material.

16. The display device of claim 15, wherein the filling member covers the capping layer.

17. A display device comprising:
a first display substrate comprising a first base layer comprising a display area and a non-display area adjacent to the display area;
a second display substrate spaced apart from the first display substrate and comprising a second base layer comprising pixel areas respectively overlapping the display area and a peripheral area adjacent to the pixel areas and color filters on the second base layer; and
a sealing member between the first display substrate and the second display substrate and overlapping the non-display area, the first display substrate comprising:
light emitting elements respectively overlapping the pixel areas;
an encapsulation layer comprising a first inorganic layer covering the light emitting elements, a second inorganic layer, and a first organic layer between the first inorganic layer and the second inorganic layer;
banks provided with openings defined therethrough to respectively overlap the pixel areas and spaced apart from each other on the encapsulation layer;
light control patterns respectively in the openings; and
a second organic layer on the second inorganic layer in the non-display area, wherein the second organic layer comprises a same material as one of the light control patterns.

18. The display device of claim 17, wherein the first display substrate comprises a capping layer that covers at least a portion of each of the banks, the light control patterns, the second inorganic layer, the first base layer, and the second organic layer, and an end of the capping layer and an end of the second inorganic layer are spaced apart from each other with the second organic layer interposed therebetween in the non-display area.

19. The display device of claim 17, wherein the material comprises titanium oxide (TiO₂).

20. The display device of claim 19, wherein the other light control patterns except the one light control pattern among the light control patterns comprise a quantum dot.
